(19) United States
(12) Patent Application Publication
(10) Pub. No.: US 2016/0223600 A1
(43) Pub. Date: Aug. 4, 2016

(54) POWER GENERATION PERFORMANCE EVALUATION METHOD AND APPARATUS FOR POWER GENERATOR SET

(71) Applicant: ENVISION ENERGY (JIANGSU) CO., LTD., Jiangsu (CN)

(72) Inventors: Xiaoyu WANG, Jiangsu (CN); Bingjie ZHAO, Jiangsu (CN); Jianing LIANG, Jiangsu (CN); Xinyu FANG, Jiangsu (CN)

(21) Appl. No.: 15/013,420

(22) Filed: Feb. 2, 2016

(30) Foreign Application Priority Data
Feb. 3, 2015 (CN) 201510056910.6

(51) Int. Cl. G01R 21/133; H02S 50/10; G01W 1/00; G01R 31/34

(52) U.S. Cl. CPC G01R 21/133; G01R 31/34; H02S 50/10; G01W 1/00

(57) ABSTRACT

A power generation performance evaluation method and an apparatus thereof for a generator set are provided according to the embodiments of the present invention, which are related to the technical field of power apparatuses and are able to provide an accurate evaluation for the power generation performance of the generator set in combination with historical operation data of the generator set. The method comprises the following steps of: acquiring historical operation data of at least one generator set; selecting training data of each generator set from the historical operation data; obtaining a longitudinal power generation amount prediction model of the at least one generator set by calculating the training data of each generator set through an artificial intelligence algorithm based on data mining; and acquiring to-be-evaluated operation data of a to-be-evaluated generator set among the at least one generator set, and inputting the to-be-evaluated operation data into a corresponding longitudinal power generation amount prediction model to detect whether the longitudinal power generation performance of the to-be-evaluated generator set is normal. Embodiments of the present invention are used for evaluation of the power generation performance of the generator set.

### FIELD OF THE INVENTION

The present invention relates to the technical field of power apparatuses, and more particularly, to a power generation performance evaluation method and apparatus for a generator set.

### BACKGROUND OF THE INVENTION

After wind power plants and photovoltaic power stations are put into operation, whether the output thereof reaches the nominal output of the system and whether the power generation performance thereof is stable and sustainable have become the top concern of operators and also become the determining factors for economic indicator of the wind power plants and the photovoltaic power stations. However, the output power of the system is fluctuant, intermittent, and random due to the wind energy and the solar energy that change randomly. This makes it difficult to evaluate the power generation performance of wind turbine generator sets and photovoltaic generator sets.

For a wind turbine set, the power generation performance of wind turbines thereof may be characterized by examining a power curve of the generator set, and a power curve examination is done by recording wind speeds at the hub height of the wind turbine generator set and the output power of the generator set corresponding to the wind speeds respectively during a certain period of time. Different output power of the wind turbine generator set recorded at different wind speeds is plotted into a curve, then the curve is adjusted to a standard air density according to a corresponding formula to obtain a standard power curve, and the power generation performance of the wind turbine generator set is analyzed based on the standard power curve. Similarly, a solar radiation strength-active power curve may be plotted to characterize the power generation performance of a photovoltaic generator set. Another way to measure the power generation performance of the system is as follows: a series of operating indices are utilized to characterize the reliability and the cost-effectiveness of the system; for example, availability, fault time, annually and monthly power generation amounts, and equivalent utilization time of wind turbine apparatuses are utilized to evaluate the power generation performance of the wind turbine generator set.

However, the power generation performance of the generator sets usually is directly related to various operation data, e.g., meteorological data of the environment where the generator sets are located, operation data of the generator sets, etc. Thus, the prior art cannot synthesize the above various data to provide an accurate power generation performance evaluation.

### SUMMARY OF THE INVENTION

Embodiments of the present invention provide a power generation performance evaluation method and an apparatus thereof for a generator set, which can provide an accurate evaluation for the power generation performance of the generator set in combination with historical operation data of the generator set.

To achieve the aforesaid objective, the embodiments of the present invention provide the following technical solutions:

In a first aspect, a performance evaluation method for a generator set is provided, and the method comprises the following steps of:

acquiring historical operation data of at least one generator set, wherein the historical operation data are used to characterize the power generation performance of the generator set;

selecting training data of each generator set from the historical operation data;

obtaining a longitudinal power generation amount prediction model of the at least one generator set by calculating the training data of each generator set through an artificial intelligence algorithm based on data mining; and

acquiring to-be-evaluated operation data of a to-be-evaluated generator set among the at least one generator set, and inputting the to-be-evaluated operation data into a corresponding longitudinal power generation amount prediction model to detect whether the longitudinal power generation performance of the to-be-evaluated generator set is normal.

In a second aspect, a performance evaluation apparatus for a generator set is provided, and the apparatus comprises:

a parameter acquiring unit, being configured to acquire historical operation data of at least one generator set, wherein the historical operation data are used to characterize the power generation performance of the generator set;

a data screening unit, being configured to select training data of each generator set from the historical operation data acquired by the parameter acquiring unit;

a calculating unit, being configured to obtain a longitudinal power generation amount prediction model of the at least one generator set by calculating the training data of each generator set which are selected by the data screening unit through an artificial intelligence algorithm based on data mining; and

a detecting unit, being configured to acquire to-be-evaluated operation data of a to-be-evaluated generator set among the at least one generator set, and input the to-be-evaluated operation data into a corresponding longitudinal power generation amount prediction model obtained by the calculating unit to detect whether the longitudinal power generation performance of the to-be-evaluated generator set is normal.

According to the power generation performance evaluation method for a generator set provided in the aforesaid solutions, the power generation performance evaluation apparatus is able to combine with the historical operation data of the generator set, and to obtain a longitudinal power generation amount prediction model of the at least one generator set by calculating the training data of each generator set through an artificial intelligence algorithm based on data mining, and then evaluate the power generation performance of the generator set through the longitudinal power generation amount prediction model so that accurate evaluation for the power generation performance of the generator set is accomplished.

### BRIEF DESCRIPTION OF THE DRAWINGS

To describe the technical solutions of embodiments of the present invention more clearly, the attached drawings necessary for description of the embodiments or the prior art will be introduced briefly herein below. Obviously, these attached drawings only illustrate some of the embodiments of the present invention, and those of ordinary skilled in the art can further obtain other drawings according to these attached drawings without making inventive efforts.

FIG. 1 is a schematic flowchart diagram of a power generation performance evaluation method for a generator set according to an embodiment of the present invention;

FIG. 2 is a schematic flowchart diagram of a power generation performance evaluation method for a generator set according to another embodiment of the present invention;

FIG. 3 is a schematic diagram of a modeling method for a longitudinal power generation amount prediction model according to an embodiment of the present invention;

FIG. 4 is a schematic diagram of a verification method for a longitudinal power generation amount prediction model according to an embodiment of the present invention;

FIG. 5 is a schematic diagram of a cluster analysis method according to an embodiment of the present invention;

FIG. 6 is a schematic diagram of a detecting method for horizontal power generation performance according to an embodiment of the present invention;

FIG. 7 is a schematic structural diagram of a power generation performance evaluation apparatus according to an embodiment of the present invention;

FIG. 8 is a schematic structural diagram of a power generation performance evaluation apparatus according to another embodiment of the present invention; and

FIG. 9 is a schematic structural diagram of a power generation performance evaluation apparatus according to yet another embodiment of the present invention.

### DETAILED DESCRIPTION OF THE PREFERRED EMBODIMENTS

Various embodiments are now being described with reference to the attached drawings in which the same reference numerals designate the same elements. Herein below, for ease of explanation, a lot of details are given to provide a complete understanding for one or more embodiments. However, it is obvious that the embodiments may also be implemented without these details. In other embodiments, well known structures and apparatuses are shown in the form of block diagrams to facilitate description for one or more embodiments.

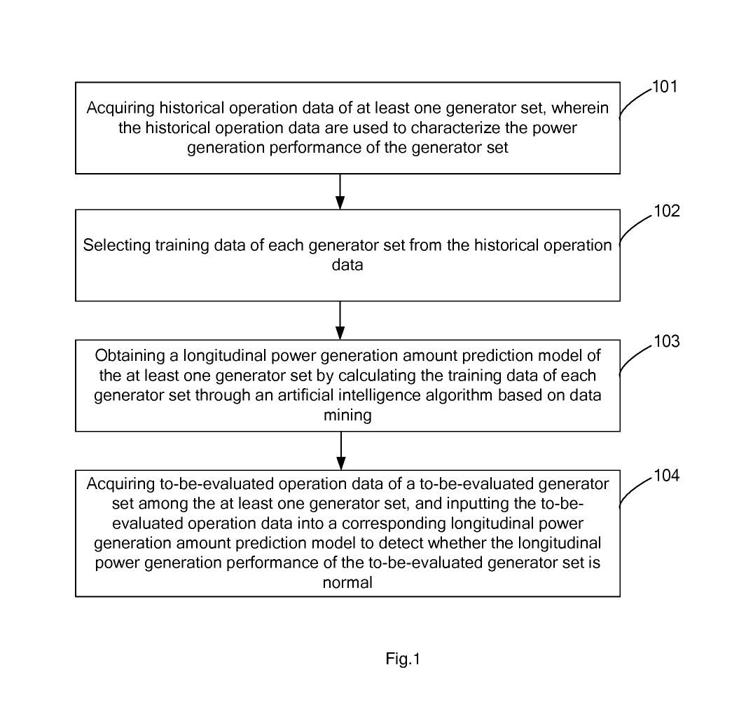

Referring to FIG. 1, a power generation performance evaluation method for a generator set is provided according to an embodiment of the present invention, and the method comprises the following steps:

101: acquiring historical operation data of at least one generator set, wherein the historical operation data are used to characterize the power generation performance of the generator set.

The generator sets claimed in the embodiment of the present invention include wind turbine generator sets and photovoltaic generator sets, but are not limited thereto. The aforesaid wind turbine generator set may be a generator set comprised of a single wind turbine generator, a transformer and transmission lines, or may be a wind power plant comprised of several wind turbine generators, transformer(s) and transmission lines. Similarly, the photovoltaic generator set may also be a generator set comprised of a single photovoltaic cell panel, a convertor and transmission lines, or may be a solar power station comprised of several photovoltaic cell panels, convertor(s), and transmission lines. Taking the photovoltaic generator set as an example, during the actual evaluation, the historical operation data of the generator set may be data that separately characterize either the performance of the photovoltaic cell panel or the performance of the converter, or may be data that characterize both the performance of the photovoltaic cell panel and the performance of the converter at the same time. Therefore, the overall performance of the generator set, or the performance of any part of the generator set (e.g., the photovoltaic cell panel, or the convertor, etc) may be evaluated.

102: selecting training data of each generator set from the historical operation data.

103: obtaining a longitudinal power generation amount prediction model of the at least one generator set by calculating the training data of each generator set through an artificial intelligence algorithm based on data mining.

For example, the artificial intelligence algorithm based on data mining in the step 103 may adopt an adaptive neuro-fuzzy inference system (ANFIS).

104: acquiring to-be-evaluated operation data of a to-be-evaluated generator set among the at least one generator set, and inputting the to-be-evaluated operation data into a corresponding longitudinal power generation amount prediction model to detect whether the longitudinal power generation performance of the to-be-evaluated generator set is normal.

According to the power generation performance evaluation method for a generator set provided in the aforesaid solutions, the power generation performance evaluation apparatus is able to combine with the historical operation data of the generator set, and to obtain a longitudinal power generation amount prediction model of the at least one generator set by calculating the training data of each generator set through an artificial intelligence algorithm based on data mining, and then evaluate the power generation performance of the generator set through the longitudinal power generation amount prediction model so that accurate evaluation for the power generation performance of the generator set is accomplished.

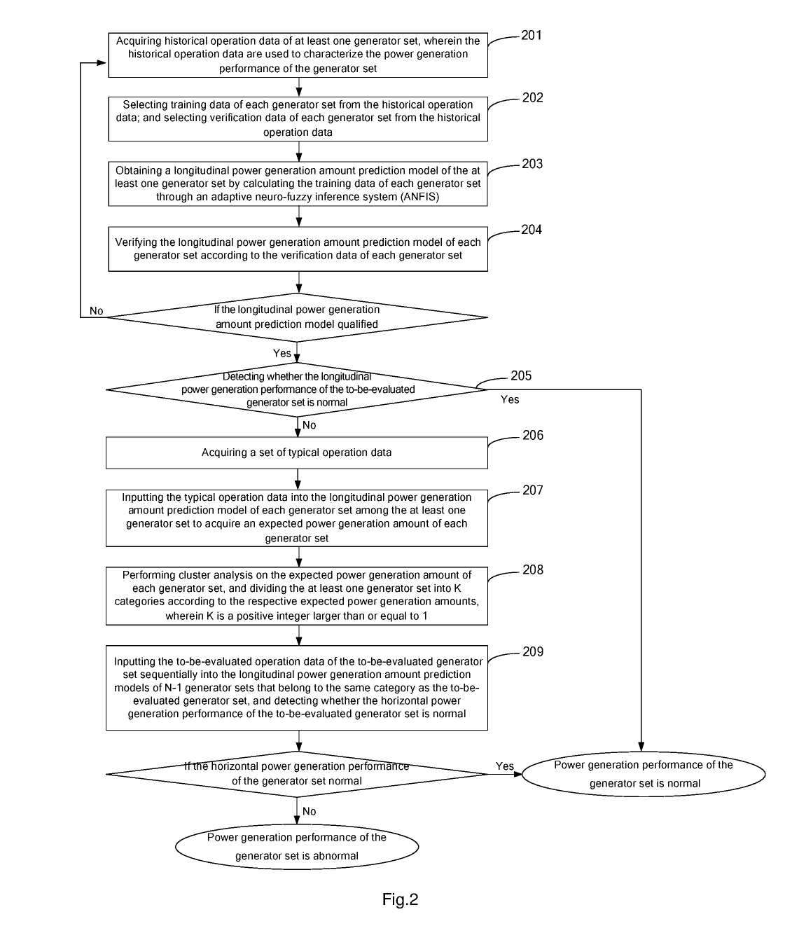

Specifically referring to FIG. 2, a power generation performance evaluation method for a generator set according to another embodiment of the present invention comprises the following steps:

201: acquiring historical operation data of at least one generator set, wherein the historical operation data are used to characterize the power generation performance of the generator set.

The generator sets may adopt wind turbine generator sets or photovoltaic generator sets, and the operation data includes meteorological data and generator set operation data. When the generator sets are wind turbine generator sets, the meteorological data includes wind speed, wind direction, environment temperature, air humidity, air pressure and turbulence intensity; and the generator set operation data includes power, rotating speed and wind turbine operating status, and wherein the wind turbine operating status includes an idling status, a power generating status and a stop status. When the generator sets are photovoltaic generator sets, the meteorological data includes optical radiation strength, environment temperature, air humidity and wind speed; and the generator set operation data includes power, and photovoltaic generator set operating status, and wherein the photovoltaic generator set operating status includes a power generating status, a no-load status and a stop status.

The method further comprises the following step after the step 201: screening the historical operation data of the at least one generator set to acquire the historical operation data of each generator set in a normal operating status.

Specifically, when the wind turbine generator set is adopted for example, invalid and unreasonable operation data may be weeded out according to the wind turbine operating status and the actual operating range (e.g., the period of time for operating) to select historical data of the wind turbine in a normal power generating status, and operation data of the wind turbine respectively in the following statuses are screened out: e.g., an internal and external factors limited power operating status, a maintenance status, a dynamic process status and a stop status due to weather. The number of the sampling points for the historical operation data is enough to establish a complete power generation amount prediction model so as to ensure the accuracy of the power generation amount prediction model. Similarly, the same technical means and reasons may be adopted for the photovoltaic generator set to screen the historical operation data, and this will not be further described herein.

202: selecting training data of each generator set from the historical operation data; and selecting verification data of each generator set from the historical operation data.

In the step 202, the training data are used to train the longitudinal power generation amount prediction model of the generator set, and the verification data are used to verify the accuracy of the longitudinal power generation amount prediction model.

Taking the wind turbine generator set as an example, the training data and the verification data in the step 202 may be selected specifically in the following way:

calculating a wind speed-active power curve of the training data and the verification data, evaluating the dispersion degree of the wind speed-active power curve by utilizing a normalized index, e.g., a normalized root mean square error (NREMS), and selecting two groups of data having the similar dispersion as the training data and the verification data respectively.

$$NREMS = 1 - \frac{\sqrt{{\sum }_{i = 1}^{n} {( {x}_{i} - {x}_{i}^{ref} )}^{2}}}{\sqrt{{\sum }_{i = 1}^{n} {( {x}_{i} - \overline{{x}^{ref}} )}^{2}}}$$

wherein x represents the active power of the wind turbine, x^{ref} represents the fitting power curve power of the wind turbine, and n represents the number of the data points. When the photovoltaic generator set is taken as an example, the training data and the verification data may be selected by calculating an optical radiation strength-active power curve.

203: obtaining a longitudinal power generation amount prediction model of the at least one generator set by calculating the training data of each generator set through an adaptive neuro-fuzzy inference system (ANFIS).

204: verifying the longitudinal power generation amount prediction model of each generator set according to the verification data of each generator set.

In the step 203, the power generation performance of the generator set is influenced by many factors, so it is a nonlinear, multivariable and complicated system. Taking the wind turbine generator set as an example, the power generation performance of the wind turbine thereof is influenced by factors such as wind speed, turbulence intensity, ambient air density, geographical condition and self-characteristics of the wind turbine. In the step 203, the modeling for the longitudinal power generation amount prediction model is accomplished through the ANFIS which is a fuzzy inference system that combines fuzzy logic with neural network. A hybrid algorithm of back propagation and least square method is adopted to respectively adjust premise parameters and conclusion parameters and automatically generate an If-Then rule. Fuzzy control has the advantages of strong robustness and that no accurate model of a controlled object being required, and the neural network has the advantages of self-learning and high control accuracy. The ANFIS has both the advantages of the fuzzy control and the advantages of the neural network, so it can well adapt to the situation where the power generation performance of the generator set is influenced by many factors.

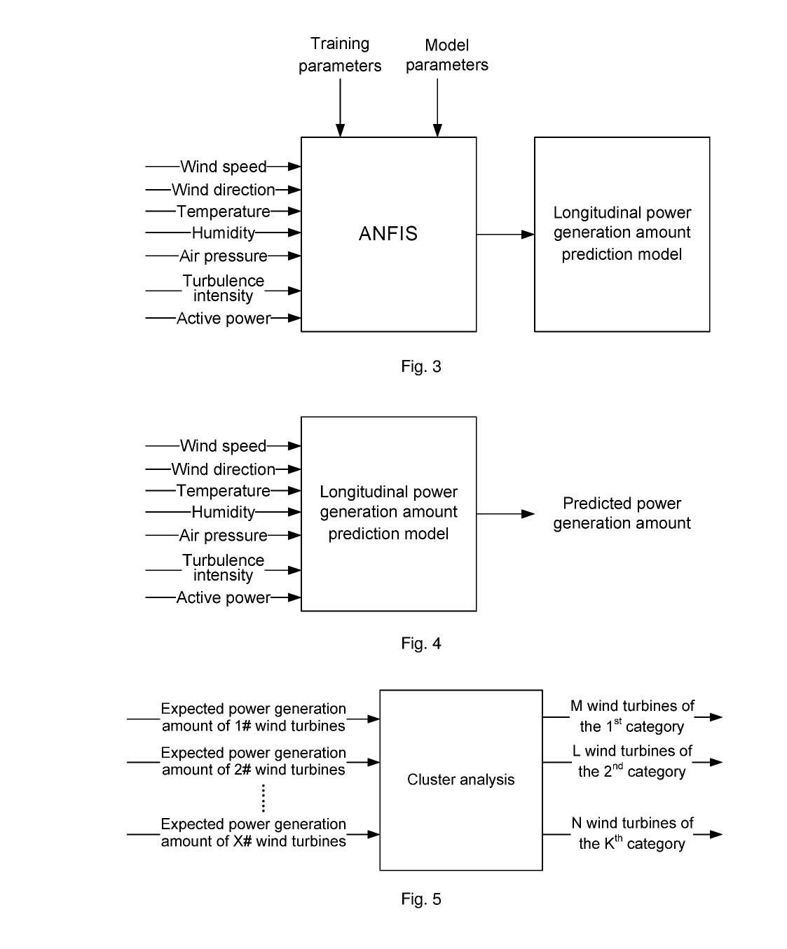

In the steps 203 and 204, the longitudinal power generation amount prediction model is established through the ANFIS (Adaptive Neuro-fuzzy Inference System) by utilizing the training data. Taking the wind turbine generator set as an example, as shown in FIG. 3, input parameters of the ANFIS include wind speed, wind direction, temperature, humidity, air pressure, turbulence intensity and active power, for example. Of course, the input parameters of the ANFIS may also include any one or more of the aforesaid parameters or include other related parameters, e.g., rotating speed of the wind turbine, and operating status of the wind turbine, etc. Using the verification data to verify the longitudinal power generation amount prediction model, and in this case, the relationships between the input parameters and output parameters of the longitudinal power generation amount prediction model are as shown in FIG. 4. When the verification data are inputted, the following formula is adopted to evaluate whether the relationship between the predicted power generation amount and the actual power generation amount is abnormal, e.g., to evaluate whether the relationship there between satisfies the following formula:

$$\frac{\begin{matrix}\vert Predicted power generation amount - \\ Actual power generation amount \vert\end{matrix}}{Actual power generation amount} < Preset value ,$$

wherein the preset value is used to determine whether the verification data are qualified, and the preset value may be determined according to the sampling precision of various input data of the longitudinal power generation amount prediction model. If the verification data are unqualified, it means that the trained longitudinal power generation amount prediction model has poor adaptability, and the longitudinal power generation amount prediction model is unqualified, and model parameters and training parameters of the ANFIS (as shown in FIG. 2) need to be adjusted for retraining. For example, the model parameters of the ANFIS include parameters such as the membership function and the number of model input variables, and the training parameters of the ANFIS include parameters such as training times, initial step length and increasing or decreasing rate of the step length.

205: acquiring to-be-evaluated operation data of a to-be-evaluated generator set among the at least one generator set, and inputting the to-be-evaluated operation data into a corresponding longitudinal power generation amount prediction model to detect whether the longitudinal power generation performance of the to-be-evaluated generator set is normal.

The step 205 comprises the following steps of: inputting the to-be-evaluated operation data into the corresponding longitudinal power generation amount prediction model to acquire a predicted power generation amount of the to-be-evaluated generator set;

determining that the longitudinal power generation performance of the to-be-evaluated generator set is normal when the relationship between the predicted power generation amount and the actual power generation amount satisfies a preset condition; and

determining that the longitudinal power generation performance of the to-be-evaluated generator set is abnormal when the relationship does not satisfy the preset condition.

During the actual operation of the wind turbine, after the actual power generation amount is obtained through power generation amount detection, a quantitative index of the change in the performance of the generator set may be determined according to the ratio between the predicted power generation amount and the actual power generation amount obtained in the aforesaid step 205. For example, the change tendency of the power generation performance of the generator set may be evaluated according to the actual power generation amounts detected during a period of time and the corresponding predicted power generation amounts.

In the steps before the step 205, the own historical operation data of a single generator set (i.e., the to-be-evaluated generator set) are utilized to evaluate the power generation performance of the to-be-evaluated generator set. To improve the reliability of the evaluation, after it is detected in the step 205 that the power generation performance of the to-be-evaluated generator set is abnormal, this embodiment of the present invention provides steps after step 206 to classify multiple generator sets into different categories according to the power generation performance. In this way, the reliability of the evaluation is improved by comparing power generation performance of generator sets that belong to the same category.

206: acquiring a set of typical operation data when the power generation performance of the to-be-evaluated generator set is abnormal.

207: inputting the typical operation data into the longitudinal power generation amount prediction model of each generator set among the at least one generator set to acquire an expected power generation amount of each generator set.

Taking the wind turbine generator set as an example, in the steps 206 and 207, data of an anemometer tower in a wind field may typically represent the wind resource condition of the wind field, so the meteorological data in the typical operation data may adopt the data of the anemometer tower in the wind field. Therefore, historical wind turbine operation data of the anemometer tower in the wind field (e.g., wind speed at the hub height, turbulence intensity, wind direction, temperature, humidity and air pressure) may be selected to serve as the input of the longitudinal power generation amount prediction model of each generator set, and then the simulated expected power generation amounts of the generator sets in a wind power station can be obtained through the longitudinal power generation amount prediction models of the wind turbines. Historical wind turbine operation data of the anemometer tower obtained at the same period of time as the training data and verification data of the generator set may be selected, to ensure that the historical operation data of the anemometer tower are the data obtained when the generator sets are operating normally so as to reduce influence of other unconsidered input factors on power generation amount prediction during the model training. If no anemometer tower data are available, reference may be made to the historical operation data of a typical wind turbine in the wind field.

208: performing cluster analysis on the expected power generation amount of each generator set, and dividing the at least one generator set into K categories according to the respective expected power generation amounts, wherein K is a positive integer larger than or equal to 1.

According to the expected power generation amount of each generator set acquired in the step 207, cluster analysis (e.g., K-Means cluster algorithm) is performed to classify the power generation performance of the generator sets. As shown in FIG. 5 (taking the wind turbine generator set as an example), wind turbines ranging from 1# to X# may be divided into K categories according to respective expected power generation amounts after taking both the precision of the longitudinal power generation amount prediction model and later evaluation requirements into consideration, and the power generation performance of wind turbines that belong to the same category is regarded as at the same level.

209: inputting the to-be-evaluated operation data of the to-be-evaluated generator set sequentially into the longitudinal power generation amount prediction models of N−1 generator sets that belong to the same category as the to-be-evaluated generator set, and detecting whether the horizontal power generation performance of the to-be-evaluated generator set is normal.

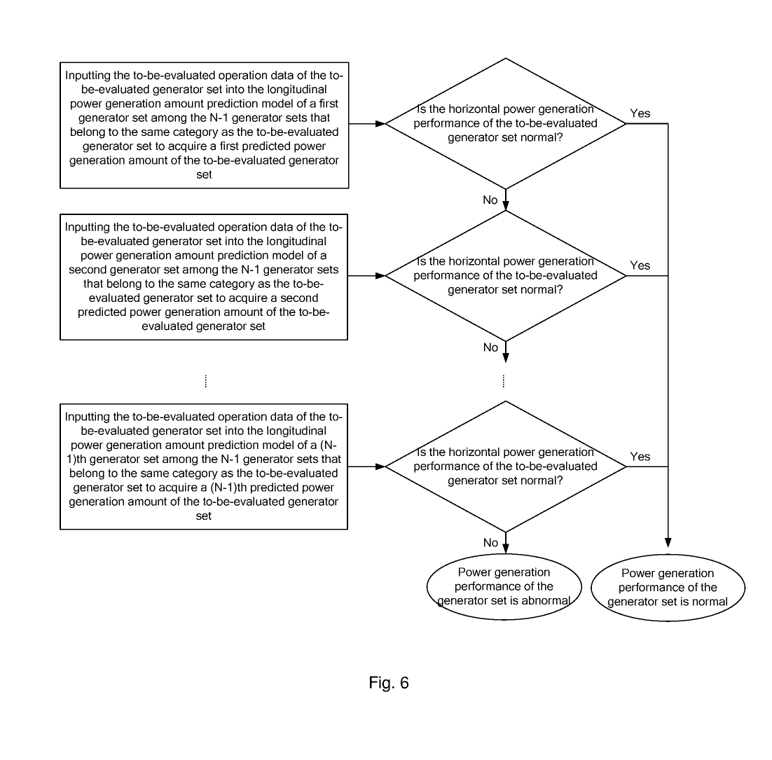

Referring to FIG. 6, the step 209 comprises the following step of: inputting the to-be-evaluated operation data of the to-be-evaluated generator set into the longitudinal power generation amount prediction model of a first generator set among the N−1 generator sets that belong to the same category as the to-be-evaluated generator set, to acquire a first predicted power generation amount of the to-be-evaluated generator set;

determining that the horizontal power generation performance of the to-be-evaluated generator set is normal when the relationship between the first predicted power generation amount and the actual power generation amount satisfies a preset condition; and

determining that the horizontal power generation performance of the to-be-evaluated generator set is abnormal when the relationship does not satisfy the preset condition, and inputting the to-be-evaluated operation data of the to-be-evaluated generator set sequentially into the longitudinal power generation amount prediction models of the other generator sets among the N−1 generator sets that belong to the same category as the to-be-evaluated generator set, to detect whether the horizontal power generation performance of the to-be-evaluated generator set is normal.

Taking the wind turbine generator set as an example, it is assumed that in the step 209 there are N wind turbines in a certain category of which the power generation performance is at the same level. To compare the power generation performance of the to-be-evaluated wind turbine with that of the other wind turbines, historical data of the other wind turbines are taken as the training data to establish N−1 horizontal power generation amount prediction models of the to-be-evaluated wind turbine (i.e., longitudinal power generation amount prediction models of the other N−1 wind turbines). The historical operation data for training the N−1 horizontal power generation amount prediction models of the to-be-evaluated wind turbine are preferably data obtained when the to-be-evaluated wind turbine is operating normally so as to reduce influence of other unconsidered input factors on power generation amount prediction during the model training.

Thus, power generation performance of the wind turbine during a to-be-evaluated period of time can be detected through the horizontal power generation amount prediction models. For each of the horizontal power generation amount prediction models, the to-be-evaluated operation data of the to-be-evaluated wind turbine are taken as the input data to evaluate the relationship between the predicted power generation amount and the actual power generation amount, e.g., to determine whether the relationship therebetween satisfies the following formula:

$$\frac{\begin{matrix}\vert Predicted power generation amount - \\ Actual power generation amount \vert\end{matrix}}{Actual power generation amount} > Preset value ,$$

and it is finally determined that the power generation performance of the wind turbine is abnormal if the aforesaid formula is satisfied.

210: acquiring the predicted power generation amount through the longitudinal power generation amount prediction model, and/or determining the change in the performance of the generator set according to the predicted power generation amount acquired through the longitudinal power generation amount prediction model.

According to the power generation performance evaluation method for a generator set provided in the aforesaid solutions, the power generation performance evaluation apparatus is able to combine with the historical operation data of the generator set, and to obtain a longitudinal power generation amount prediction model of the at least one generator set by calculating the training data of each generator set through an adaptive neuro-fuzzy inference system (ANFIS), and then evaluate the power generation performance of the generator set through the longitudinal power generation amount prediction model so that accurate evaluation for the power generation performance of the generator set is accomplished.

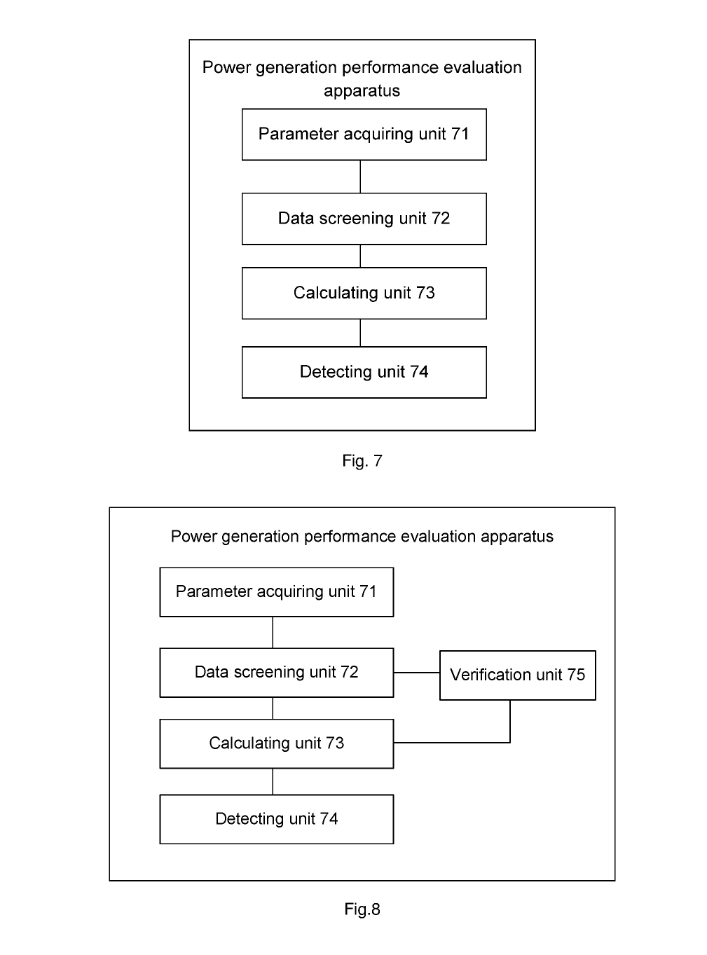

A power generation performance evaluation apparatus is provided by an embodiment of the present invention to implement the aforesaid power generation performance evaluation method for a generator set. Referring to FIG. 7, the apparatus comprises:

a parameter acquiring unit 71, being configured to acquire historical operation data of at least one generator set, wherein the historical operation data are used to characterize the power generation performance of the generator set;

a data screening unit 72, being configured to select training data of each generator set from the historical operation data acquired by the parameter acquiring unit 71;

a calculating unit 73, being configured to obtain a longitudinal power generation amount prediction model of the at least one generator set by calculating the training data of each generator set which are selected by the data screening unit 72 through an artificial intelligence algorithm based on data mining; and

a detecting unit 74, being configured to acquire to-be-evaluated operation data of a to-be-evaluated generator set among the at least one generator set, and input the to-be-evaluated operation data into a corresponding longitudinal power generation amount prediction model obtained by the calculating unit to detect whether the longitudinal power generation performance of the to-be-evaluated generator set is normal.

The power generation performance evaluation apparatus provided in the aforesaid solutions is able to combine with the historical operation data of the generator set, and to obtain a longitudinal power generation amount prediction model of the at least one generator set by calculating the training data of each generator set through an artificial intelligence algorithm based on data mining, and then evaluate the power generation performance of the generator set through the longitudinal power generation amount prediction model so that accurate evaluation for the power generation performance of the generator set is accomplished.

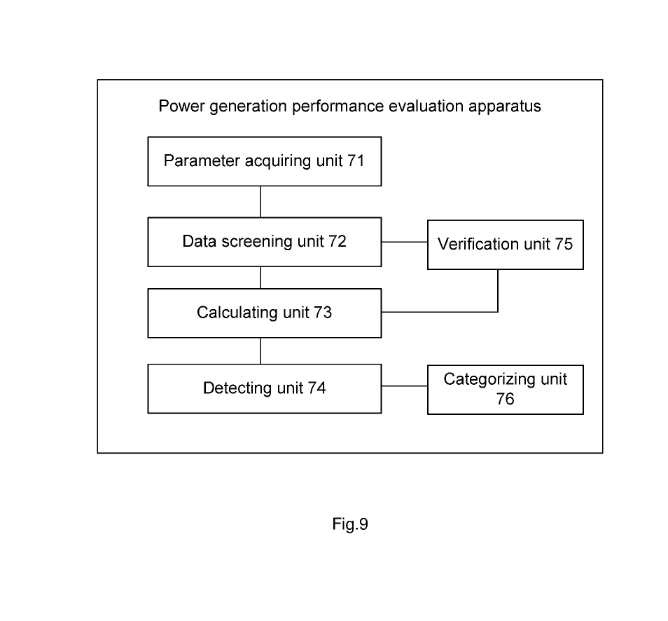

Optionally, referring to FIG. 8, the apparatus further comprises a verification unit 75;

the data screening unit 72 is further configured to select verification data of each generator set from the historical operation data acquired by the parameter acquiring unit 71; and

the verification unit 75 is configured to verify the longitudinal power generation amount prediction model of each generator set according to the verification data of each generator set selected by the data screening unit 72.

Optionally, the data screening unit 72 is further configured to screen the historical operation data of the at least one generator set to acquire the historical operation data of each generator set in a normal operating status.

Further, referring to FIG. 9, the parameter acquiring unit 71 is further configured to acquire a set of typical operation data when the power generation performance of the to-be-evaluated generator set is abnormal;

the detecting unit 74 is further configured to input the typical operation data acquired by the parameter acquiring unit 71 into the longitudinal power generation amount prediction model of each generator set among the at least one generator set to acquire an expected power generation amount of each generator set;

a categorizing unit 76 is configured to perform cluster analysis on the expected power generation amount of each generator set acquired by the detecting unit 74, and divide the at least one generator set into K categories according to the respective expected power generation amounts, wherein K is a positive integer larger than or equal to 1; and

the detecting unit 74 is further configured to input the to-be-evaluated operation data of the to-be-evaluated generator set sequentially into the longitudinal power generation amount prediction models of N−1 generator sets that belong to the same category as the to-be-evaluated generator set, and detect whether the horizontal power generation performance of the to-be-evaluated generator set is normal.

Further, the detecting unit 74 is specifically configured to input the to-be-evaluated operation data into the corresponding longitudinal power generation amount prediction model to acquire a predicted power generation amount of the to-be-evaluated generator set; determine that the longitudinal power generation performance of the to-be-evaluated generator set is normal when the relationship between the predicted power generation amount and the actual power generation amount satisfies a preset condition; and determine that the longitudinal power generation performance of the to-be-evaluated generator set is abnormal when the relationship does not satisfy the preset condition.

Further speaking, the detecting unit 74 is specifically configured to input the to-be-evaluated operation data of the to-be-evaluated generator set into the longitudinal power generation amount prediction model of a first generator set among the N−1 generator sets that belong to the same category as the to-be-evaluated generator set to acquire a first predicted power generation amount of the to-be-evaluated generator set; determine that the horizontal power generation performance of the to-be-evaluated generator set is normal when the relationship between the first predicted power generation amount and the actual power generation amount satisfies the preset condition; and determine that the horizontal power generation performance of the to-be-evaluated generator set is abnormal when the relationship does not satisfy the preset condition, and input the to-be-evaluated operation data of the to-be-evaluated generator set sequentially into the longitudinal power generation amount prediction models of the other generator sets among the N−1 generator sets that belong to the same category as the to-be-evaluated generator set to detect whether the horizontal power generation performance of the to-be-evaluated generator set is normal.

Optionally, the detecting unit 74 is further configured to acquire the predicted power generation amount through the longitudinal power generation amount prediction model, and/or to determine the change in the performance of the generator set according to the predicted power generation amount acquired through the longitudinal power generation amount prediction model.

The generator sets in the aforesaid embodiments include a wind turbine generator set or a photovoltaic generator set, and the operation data includes meteorological data and generator set operation data. When the generator sets are wind turbine generator sets, the meteorological data includes wind speed, wind direction, environment temperature, air humidity and air pressure; and the generator set operation data includes power, rotating speed and wind turbine operating status, and wherein the wind turbine operating status includes an idling status, a power generating status and a stop status. When the generator sets are photovoltaic generator sets, the meteorological data includes optical radiation strength, environment temperature, air humidity and wind speed; and the generator set operation data includes power, and photovoltaic generator set operating status, and wherein the photovoltaic generator set operating status includes a power generating status, a no-load status and a stop status.

It shall be noted that, various functional units of the apparatus in the aforesaid embodiments may be processors individually disposed in the power generation performance evaluation apparatus, or may be integrated into a certain processor of the power generation performance evaluation apparatus, or may be stored into a storage of the power generation performance evaluation apparatus in the form of program codes, and the functions of the aforesaid units are invoked and executed by a certain processor of a first apparatus. The aforesaid processor may be a central processing unit (CPU), or an application specific integrated circuit (ASIC), or may be configured to be one or more integrated circuits for implementing the embodiments of the present invention.

What described above are only the embodiments of the present invention, but are not intended to limit the scope of the present invention. Any modifications or replacements that may be readily envisioned by those skilled in the art within the technical scope of the present invention shall all be covered within the scope of the present invention. Thus, the scope claimed in the present invention shall be governed by the claims.

What is claimed is:

1. A power generation performance evaluation method for a generator set, comprising the following steps of:
acquiring historical operation data of at least one generator set, wherein the historical operation data are used to characterize the power generation performance of the generator set;
selecting training data of each generator set from the historical operation data;
obtaining a longitudinal power generation amount prediction model of the at least one generator set by calculating the training data of each generator set through an artificial intelligence algorithm based on data mining; and
acquiring to-be-evaluated operation data of a to-be-evaluated generator set among the at least one generator set, and inputting the to-be-evaluated operation data into a corresponding longitudinal power generation amount prediction model to detect whether the longitudinal power generation performance of the to-be-evaluated generator set is normal.

2. The method of claim 1, further comprising the following steps of:
selecting verification data of each generator set from the historical operation data;
the method further comprising the following step after the step of obtaining a longitudinal power generation amount prediction model of the at least one generator set by calculating the training data of each generator set through an artificial intelligence algorithm based on data mining:
verifying the longitudinal power generation amount prediction model of each generator set according to the verification data of each generator set.

3. The method of claim 1, further comprising the following step before the step of selecting training data of each generator set from the historical operation data:
screening the historical operation data of the at least one generator set to acquire the historical operation data of each generator set in a normal operating status.

4. The method of claim 1, further comprising the following steps of:
acquiring a set of typical operation data when the power generation performance of the to-be-evaluated generator set is abnormal;
inputting the typical operation data into the longitudinal power generation amount prediction model of each generator set among the at least one generator set to acquire an expected power generation amount of each generator set;
performing cluster analysis on the expected power generation amount of each generator set, and dividing the at least one generator set into K categories according to the respective expected power generation amounts, wherein K is a positive integer larger than or equal to 1; and
inputting the to-be-evaluated operation data of the to-be-evaluated generator set sequentially into the longitudinal power generation amount prediction models of N−1 generator sets that belong to the same category as the to-be-evaluated generator set, and detecting whether the horizontal power generation performance of the to-be-evaluated generator set is normal.

5. The method of claim 1, wherein the step of inputting the to-be-evaluated operation data into a corresponding longitudinal power generation amount prediction model to detect whether the longitudinal power generation performance of the to-be-evaluated generator set is normal comprises the following steps of:
inputting the to-be-evaluated operation data into the corresponding longitudinal power generation amount prediction model to acquire a predicted power generation amount of the to-be-evaluated generator set;
determining that the longitudinal power generation performance of the to-be-evaluated generator set is normal when the relationship between the predicted power generation amount and the actual power generation amount satisfies a preset condition; and
determining that the longitudinal power generation performance of the to-be-evaluated generator set is abnormal when the relationship does not satisfy the preset condition.

6. The method of claim 4, wherein the step of inputting the to-be-evaluated operation data of the to-be-evaluated generator set sequentially into the longitudinal power generation amount prediction models of N−1 generator sets that belong to the same category as the to-be-evaluated generator set, and detecting whether the horizontal power generation performance of the to-be-evaluated generator set is normal comprises the following steps of:
inputting the to-be-evaluated operation data of the to-be-evaluated generator set into the longitudinal power generation amount prediction model of a first generator set among the N−1 generator sets that belong to the same category as the to-be-evaluated generator set to acquire a first predicted power generation amount of the to-be-evaluated generator set;
determining that the horizontal power generation performance of the to-be-evaluated generator set is normal when the relationship between the first predicted power generation amount and the actual power generation amount satisfies a preset condition; and
determining that the horizontal power generation performance of the to-be-evaluated generator set is abnormal when the relationship does not satisfy the preset condition, and inputting the to-be-evaluated operation data of the to-be-evaluated generator set sequentially into the longitudinal power generation amount prediction models of the other generator sets among the N−1 generator sets that belong to the same category as the to-be-evaluated generator set to detect whether the horizontal power generation performance of the to-be-evaluated generator set is normal.

7. The method of claim 6, further comprising the following step of:
acquiring the predicted power generation amount through the longitudinal power generation amount prediction model; and/or
determining the change in the performance of the generator set according to the predicted power generation amount acquired through the longitudinal power generation amount prediction model.

8. The method of claim 1, wherein the artificial intelligence algorithm based on data mining includes an adaptive neuro-fuzzy inference system (ANFIS).

9. The method of claim 1, wherein the generator sets include wind turbine generator sets or photovoltaic generator sets.

10. The method of claim 9, wherein the operation data includes meteorological data and generator set operation data.

11. The method of claim 10, wherein the generator sets are wind turbine generator sets, the meteorological data includes wind speed, wind direction, environment temperature, air humidity, air pressure and turbulence intensity; and the generator set operation data includes power, rotating speed and wind turbine operating status, and wherein the wind turbine operating status includes an idling status, a power generating status and a stop status.

12. The method of claim 10, wherein the generator sets are photovoltaic generator sets, the meteorological data includes optical radiation strength, environment temperature, air humidity and wind speed; and the generator set operation data includes power, and photovoltaic generator set operating status, and wherein the photovoltaic generator set operating status includes a power generating status, a no-load status and a stop status.

13. A power generation performance evaluation apparatus, comprising:
a parameter acquiring unit, being configured to acquire historical operation data of at least one generator set, wherein the historical operation data are used to characterize the power generation performance of the generator set;
a data screening unit, being configured to select training data of each generator set from the historical operation data acquired by the parameter acquiring unit;
a calculating unit, being configured to obtain a longitudinal power generation amount prediction model of the at least one generator set by calculating the training data of each generator set which are selected by the data screening unit through an artificial intelligence algorithm based on data mining; and
a detecting unit, being configured to acquire to-be-evaluated operation data of a to-be-evaluated generator set among the at least one generator set, and input the to-be-evaluated operation data into a corresponding longitudinal power generation amount prediction model obtained by the calculating unit to detect whether the longitudinal power generation performance of the to-be-evaluated generator set is normal.

14. The apparatus of claim 13, further comprising a verification unit;
wherein the data screening unit is further configured to select verification data of each generator set from the historical operation data acquired by the parameter acquiring unit; and
the verification unit is configured to verify the longitudinal power generation amount prediction model of each generator set according to the verification data of each generator set selected by the data screening unit.

15. The apparatus of claim 13, wherein the data screening unit is further configured to screen the historical operation data of the at least one generator set to acquire the historical operation data of each generator set in a normal operating status.

16. The apparatus of claim 13, wherein
the parameter acquiring unit is further configured to acquire a set of typical operation data when the power generation performance of the to-be-evaluated generator set is abnormal;
the detecting unit is further configured to input the typical operation data acquired by the parameter acquiring unit into the longitudinal power generation amount prediction model of each generator set among the at least one generator set to acquire an expected power generation amount of each generator set;
a categorizing unit is configured to perform cluster analysis on the expected power generation amount of each generator set acquired by the detecting unit, and divide the at least one generator set into K categories according to the respective expected power generation amounts, wherein K is a positive integer larger than or equal to 1; and
the detecting unit is further configured to input the to-be-evaluated operation data of the to-be-evaluated generator set sequentially into the longitudinal power generation amount prediction models of N−1 generator sets that belong to the same category as the to-be-evaluated generator set, and detect whether the horizontal power generation performance of the to-be-evaluated generator set is normal.

17. The apparatus of claim 13, wherein the detecting unit is specifically configured to input the to-be-evaluated operation data into the corresponding longitudinal power generation amount prediction model to acquire a predicted power generation amount of the to-be-evaluated generator set; determine that the longitudinal power generation performance of the to-be-evaluated generator set is normal when the relationship between the predicted power generation amount and the actual power generation amount satisfies a preset condition; and determine that the longitudinal power generation performance of the to-be-evaluated generator set is abnormal when the relationship does not satisfy the preset condition.

18. The apparatus of claim 16, wherein the detecting unit is specifically configured to input the to-be-evaluated operation data of the to-be-evaluated generator set into the longitudinal power generation amount prediction model of a first generator set among the N−1 generator sets that belong to the same category as the to-be-evaluated generator set to acquire a first predicted power generation amount of the to-be-evaluated generator set;
determine that the horizontal power generation performance of the to-be-evaluated generator set is normal when the relationship between the first predicted power generation amount and the actual power generation amount satisfies a preset condition; and
determine that the horizontal power generation performance of the to-be-evaluated generator set is abnormal when the relationship does not satisfy the preset condition, and input the to-be-evaluated operation data of the to-be-evaluated generator set sequentially into the longitudinal power generation amount prediction models of the other generator sets among the N−1 generator sets that belong to the same category as the to-be-evaluated generator set to detect whether the horizontal power generation performance of the to-be-evaluated generator set is normal.

19. The apparatus of claim 18, wherein
the detecting unit is further configured to acquire the predicted power generation amount through the longitudinal power generation amount prediction model, and/or to determine the change in the performance of the generator set according to the predicted power generation amount acquired through the longitudinal power generation amount prediction model.

20. The apparatus of claim 13, wherein the artificial intelligence algorithm based on data mining includes an adaptive neuro-fuzzy inference system (ANFIS).

21. The apparatus of claim 13, wherein the generator sets include wind turbine generator sets or photovoltaic generator sets.

22. The apparatus of claim 21, wherein the operation data includes meteorological data and generator set operation data.

23. The apparatus of claim 22, wherein the generator sets are wind turbine generator sets, the meteorological data includes wind speed, wind direction, environment temperature, air humidity and air pressure; and the generator set operation data includes power, rotating speed and wind turbine operating status, and wherein the wind turbine operating status includes an idling status, a power generating status and a stop status.

24. The apparatus of claim 22, wherein the generator sets are photovoltaic generator sets, the meteorological data includes optical radiation strength, environment temperature, air humidity and wind speed; and the generator set operation data includes power, and photovoltaic generator set operating status, and wherein the photovoltaic generator set operating status includes a power generating status, a no-load status and a stop status.
